(19) United States
(12) Patent Application Publication
(10) Pub. No.: US 2002/0173079 A1
(43) Pub. Date: Nov. 21, 2002

(54) Dual damascene integration scheme using a bilayer interlevel dielectric

(76) Inventor: Erdem Kaltalioglu, Wappingers Falls, NY (US)

Correspondence Address: Infineon Technologies North America Corp., c/o Siemens Corporation, Intellectual Property Department, 186 Wood Avenue South, Iselin, NJ, 08830, US

(21) Appl. No.: 09/751,476

(22) Filed: Dec. 28, 2000

(51) Int. Cl. H01L 21/44

(52) U.S. Cl. 438/118

(57) ABSTRACT

A semiconductor device structure and a method for forming the structure include the following. A first dielectric layer is formed over a substrate, the first dielectric having afirst dielectric constant characteristic. A via is formed in a portion of the first dielectric layer. A second dielectric layer is formed over the first dielectric layer, the second dielectric layer having a second dielectric constant characteristic lower than the first dielectric constant. A trench is formed in a portion of the second dielectric layer with a portion of the trench being formed over the via. A semiconductor structure includes a semiconductor substrate and a dielectric layer disposed over the substrate, the dielectric layer having a first trench. A first metal layer is disposed in the first trench. A first layer of a material having a first dielectric constant is disposed over the dielectric layer, the first layer having a via in registration with the metal disposed in the first trench. A second layer of a material having a second dielectric constant is disposed over the first layer of material, the second layer having a second trench in registration with the via. The first dielectric constant is higher than the second dielectric constant. A second metal layer is disposed in the via and second trench, the second metal layer being in contact with the first metal layer.

### BACKGROUND

This invention relates to semiconductor structures and methods for forming such structures and more particularly to structures having dual damascene recesses formed in interlevel dielectrics.

One method for forming interconnects in a semiconductor structure is a so-called dual damascene process. A dual damascene process starts with the deposition of a dielectric layer, typically an oxide layer, disposed over circuitry formed in a single crystal body, for example silicon. The oxide layer is etched to form a trench having a pattern corresponding to a pattern of vias and wires for interconnection of elements of the circuitry. Vias are openings in the oxide through which different layers of the structure are electrically interconnected, and the pattern of the wires is defined by trenches in the oxide. Thus, the vias and trenches are defined by two separate sets of photolithographic and etch steps. Metal is deposited to fill the openings in the oxide layer. Subsequently, excess metal is removed by polishing. The process is repeated as many times as necessary to form the required interconnections. Thus, a dual damascene structure has a trench in an upper portion of a dielectric layer and a via terminating at the bottom of the trench and passing through a lower portion of the dielectric layer.

The fabrication of dual damascene structures presents challenges. For example, the photolithography of vias and trenches is difficult because, subsequent to the definition of one of these two types of apertures, the photolithography for the other type of aperture must be done on a surface with non-planar topography. Further, the relatively high dielectric constant of the silicon dioxide typically used as an interlevel dielectric results in a high capacitance between lines, with parasitic capacitance or “crosstalk” between metal interconnect lines. Materials with low dielectric constants (low-k) are available for use as interlevel dielectrics. Organic low-k materials, however, lack the mechanical strength that silicon dioxide provides. Also, organic low-k materials are not as thermally conductive as silicon dioxide. The use of organic low-k materials can lead, therefore, to heat build-up which reduces the performance of the device. Inorganic low-k materials, on the other hand, present the patterning challenges discussed above.

### SUMMARY

In accordance with one aspect of the present invention, a method for forming a semiconductor device includes the following steps. A first dielectric layer is formed over a substrate. A via is formed in a portion of the first dielectric layer. A second dielectric layer is formed over the first dielectric layer, with the second dielectric layer being formed with a lower dielectric constant than the dielectric constant of the first dielectric layer. A trench is formed in a portion of the second dielectric layer with a portion of said trench being formed over the via.

In one embodiment of this aspect of the invention, the first dielectric layer is an inorganic material, and in another embodiment, the second dielectric layer is an organic material.

In accordance with another aspect of the invention, a method for forming a semiconductor device includes the following steps. A first metallization layer is deposited over a substrate. The first metallization layer is patterned to define an electrical conductor. A first dielectric layer is formed over the first metallization layer. A via is formed in a portion of the first dielectric layer. A second dielectric layer is formed over the first dielectric layer, the second dielectric layer being formed with a dielectric constant lower than the dielectric constant of the first dielectric layer. A trench is formed in a portion of the second dielectric layer with a portion of the trench being formed over the via. A second metallization layer is deposited. The second metallization layer fills the via and the trench, and a portion of the first metallization layer is in contact with a portion of the second metallization layer.

In one embodiment of this aspect, the via has a first width and the trench has a second width and the second width is at least equal to the first width.

In accordance with yet another aspect of the invention, a method for forming a semiconductor device includes the following steps. An inorganic dielectric layer is formed over a substrate. A via is formed in a portion of the inorganic dielectric layer. An organic dielectric layer is formed over the inorganic dielectric layer. A trench is formed in a portion of the organic dielectric layer, with a portion of the trench being formed over the via.

In accordance with still another aspect of the invention, a semiconductor structure includes a semiconductor substrate, and a dielectric layer disposed over the substrate. The dielectric layer has a first trench. A first metal layer is disposed in the first trench. A first layer of a material having a first dielectric constant is disposed over the dielectric layer. The first layer has a via in registration with the metal disposed in the first trench. A second layer of a material having a second dielectric constant is disposed over the first layer of material. The second layer has a second trench in registration with the via. A second metal layer is disposed in the via and the second trench. The second metal layer is in contact with the first metal layer. The first dielectric constant is higher than the second dielectric constant.

In one embodiment of this aspect, the first layer of a material comprises an inorganic material. In another embodiment, the second layer of a material is an organic material.

In accordance with yet another aspect of the invention, a semiconductor structure includes a semiconductor substrate, with a dielectric layer disposed over the substrate. The dielectric layer has a first trench, and a first metal layer is disposed in the first trench. A layer of an inorganic dielectric material is disposed over the dielectric layer. The inorganic dielectric layer has a via in registration with the metal disposed in the first trench. A layer of an organic material is disposed over the layer of inorganic dielectric material. The layer of organic material has a second trench in registration with the via. A second metal layer is disposed in the via and second trench. The second metal layer is in contact with the first metal layer.

The processes and structure described above ensure that a planar surface is available for the photolithography of both vias and trenches, thereby providing a wider process window. Further, by using an inorganic material for one layer of the interlevel dielectric and an organic layer for the second layer, a high etch selectivity is provided between the two layers of the interlevel dielectric, thereby further increasing the process window for forming vias and trenches. This high etch selectivity enables one to accurately control the depth of the trench.

The structure of the invention decreases parasitic capacitance between metal lines disposed in trenches. Because the material in which the trenches for the lines are defined has a relatively low dielectric constant, crosstalk between metal lines is reduced. Further, by using an interlevel dielectric layer which includes an inorganic layer beneath an organic layer, one has the dual advantage of mechanical stability provided by the inorganic layer and the planarizing effect of the organic material. Moreover, the inorganic layer, in addition to providing mechanical stability to the via, also helps to dissipate heat, thereby decreasing heat build-up in the structure during operation. Finally, the efficient dissipation of heat reduces overall thermal expansion.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of a semiconductor structure; and

FIGS. 2 through 8 are cross-sectional views of the semiconductor structure of FIG. 1 at various stages in the fabrication thereof in accordance with one embodiment of the invention.

Like reference symbols in the various drawings indicate like elements.

### DETAILED DESCRIPTION

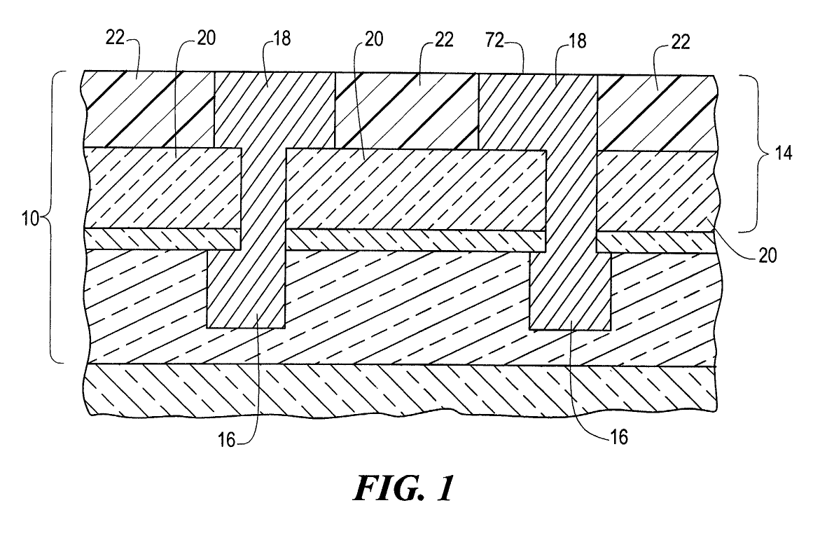

Referring to FIG. 1, a dual damascene structure 10 is formed on a silicon substrate 12. Structure 10 has a bilayer interlayer dielectric 14, as well as a first metal layer 16 and a second metal layer 18. Bilayer interlayer dielectric 14 comprises two layers: an inorganic dielectric layer 20 and an organic dielectric layer 22 having a low dielectric constant.

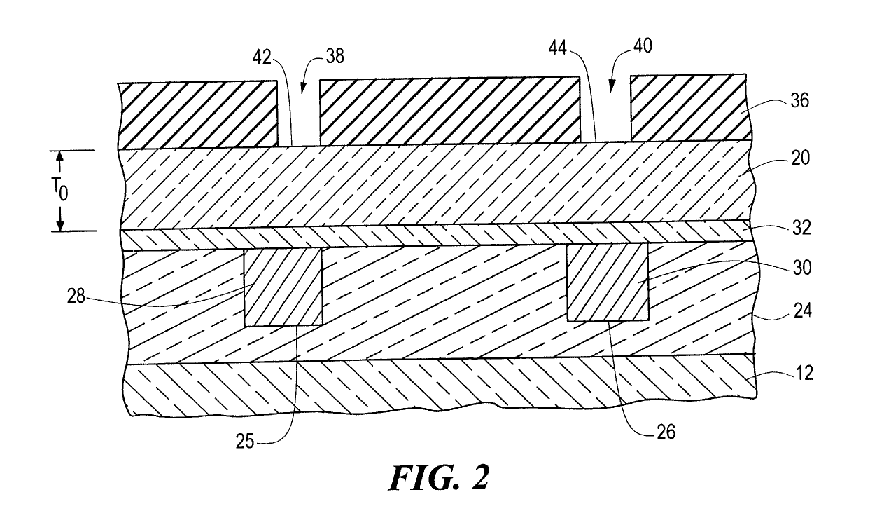

Referring also to FIG. 2, dual damascene structure 10 is formed with the following steps. First, an oxide layer 24 is deposited over silicon substrate 12, and trenches 25, 26 are formed by etching, using methods well known to those skilled in the art. In accordance with a damascene process, a first metal layer, e.g. copper, is deposited over the oxide layer 24. A portion of the metal layer located outside of trenches 25, 26 is removed to define metal electrical conductors 28, 30 in trenches 25, 26. A silicon nitride (Si₃N₄) layer 32 is then deposited over the substrate 12, including over oxide layer 24 and metal conductors 28, 30, to act as an etch stop for subsequent processing, to protect metal conductors 28, 30 from subsequent processing, and to protect the first metal layer from oxidation. Further, because in practice, dual damascene structure 10 is repeated several times on substrate 12, silicon nitride layer 32 is located below upper level metal conductors (not shown), and layer 32 prevents copper diffusion from upper layer metal conductors into substrate 12. Alternatively, layer 32 may be another capping material, such as SiCH. The above preliminary steps are performed with methods well-known to those skilled in the art. An interlevel dielectric layer 20 is then deposited over the nitride layer 32. Dielectric 20 is, e.g., an inorganic material, such as silicon dioxide (SiO₂) deposited by PECVD. Silicon dioxide has a relatively high dielectric constant of k=4.1. Depending on the application, this dielectric layer 20 has a thickness T₀of, e.g., 0.5 m. A first photoresist layer 36 is spun onto the upper surface of dielectric layer 20. Apertures 38, 40 are formed in photoresist layer 36, thereby exposing portions 42, 44 of dielectric 20. Apertures 38, 40 are formed in registration with first metal electrical conductors 28, 30.

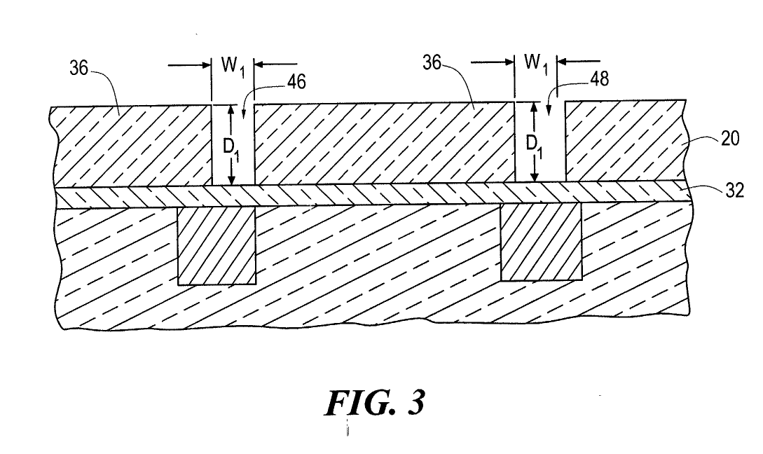

Referring also to FIG. 3, vias 46, 48 are formed in dielectric 20 at exposed portions 42, 44. Vias 46, 48 extend through dielectric 20, with nitride layer 32 defining a side of each via 46, 48. Vias 46, 48 are formed by e.g. dry etching dielectric 20 through apertures 38, 40 in photoresist 36. Nitride layer 32 acts as an etch stop. The dry etch is performed by using, e.g., an IPS Centura system, manufactured by Applied Materials, Inc., Santa Clara, Calif. The etch parameters are standard etch parameters provided by the manufacturer of the etch equipment. Vias 46, 48 have a depth D₁ of0.5 μm and a width W₁ of 0.3 m. After the completion of the dry etch, photoresist 36 is stripped off substrate 12, with methods well known to those skilled in the art.

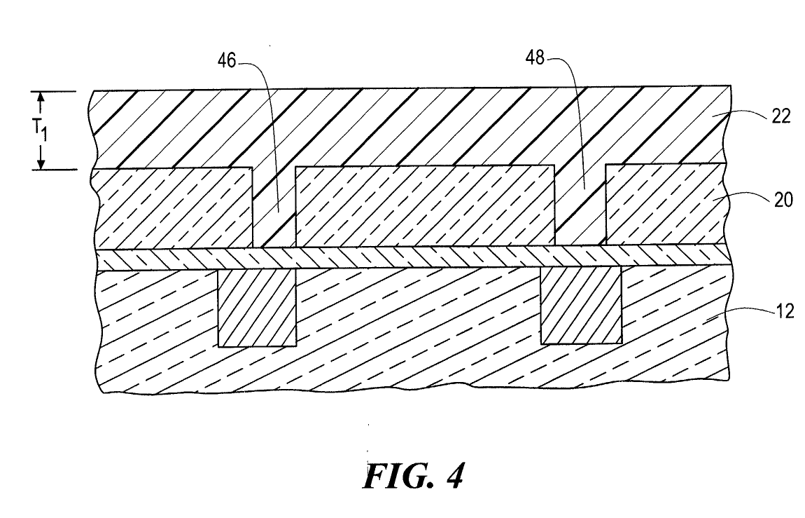

Referring to FIG. 4, a low-k material 22 is provided over dielectric 20 by, e.g., spinning material 22 over substrate 12. Material 22 is, e.g. an organic low-k material, such as SiLK™ resin, manufactured by The Dow Chemical Company, Wilmington, Delaware. Material 22 has a relatively low dielectric constant. For example, SiLK™ has a dielectric constant of approximately k=2.7. Material 22 is highly viscous, and therefore fills vias 46, 48, planarizing the topography of dielectric layer 20 and vias 46, 48. Material 22 has a hardness which is less than a hardness of dielectric 20. For example, SiLK™ has a hardness of 0.46 GPa and silicon dioxide has a hardness of 8.2 GPa. Material 22 has a thickness T₁ of 0.4 μm, measured over dielectric 20.

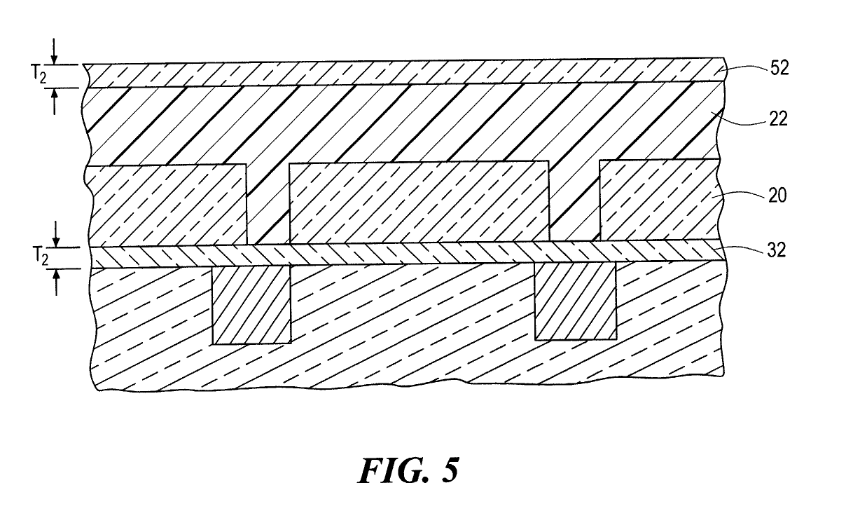

Referring to FIG. 5, a silicon nitride layer 52 is deposited on low-k material 22, e.g. by plasma-enhanced chemical vapor deposition (PECVD) or a high density plasma (HDP) CVD system, such as with a Concept Two SEQUEL Express™ or a Concept Three SPEED™ system, respectively, from Novellus Systems, Inc., located in San Jose, Calif. Alternatively, layer 52 may be an oxide or other suitable material. Nitride layer 52 has a thickness T₂ of 0.05μm. If both layer 52 and layer 32 are the same material, T₂ is greater than a thickness T₃ of layer 32. Nitride layer 52 will be patterned to form a hard mask.

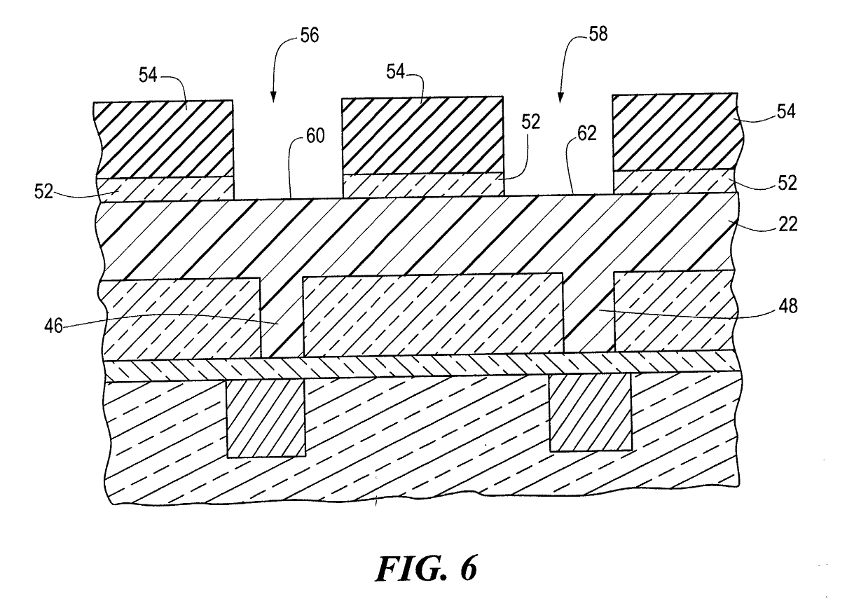

Referring to FIG. 6, a second photoresist layer 54 is spun on over nitride layer 52. Photoresist layer 54 is patterned to define apertures 56, 58, revealing portions of nitride layer 52. Apertures 56, 58 are in registration with vias 46, 48. Portions of nitride layer 52 which are revealed by apertures 56, 58 in photoresist 54 are etched away in a dry etch which is selective to material 22, for example in a fluorine-containing plasma chemistry. This etch may be carried out in, e.g., an IPS Centura system from Applied Materials, Inc. Nitride layer 52 thereby forms a mask, exposing portions 60, 62 of material 22.

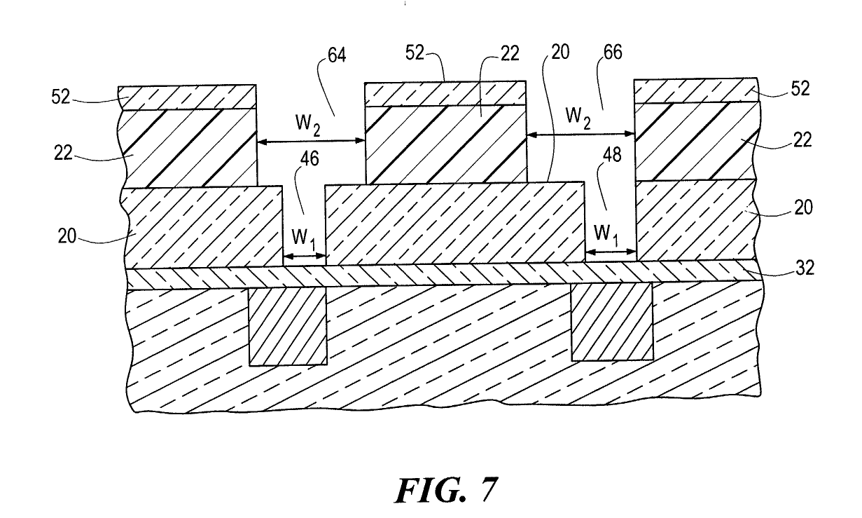

Referring to FIG. 7, portions 60, 62 of material 22, exposed by portions of nitride layer 52, are etched away in an oxygen-containing plasma in, e.g., an IPS Centura system from Applied Materials, Inc. This etch forms trenches 64, 66 in material 22, and removes material 22 from vias 46, 48. Trenches 64, 66 have a width W₂, which is equal to or greater than a width W₁ of vias 46, 48. W₂ is, for example, 0.35μm, and W₁ is, for example, 0.3 m. Second photoresist layer 54 is stripped off in the oxygen-containing plasma, during the etch of material 22. The oxygen-containing plasma parameters provide an etch for material 22 which is highly selectively to dielectric 20, as well as to nitride mask 52 and nitride etch stop 32. The etch selectivity between SiLK™ and silicon dioxide is, e.g., 25:1. The etch selectivity between SiLK™ and silicon nitride is, e.g., 20:1. Thus, the etch of material 22 includes a timed overetch step which efficiently removes material 22 without significantly attacking dielectric 20, nitride etch stop 32, and nitride mask 52. The duration of the overetch step can also be calculated as a percentage of the time required to etch material 22, e.g. 20% - 30%.

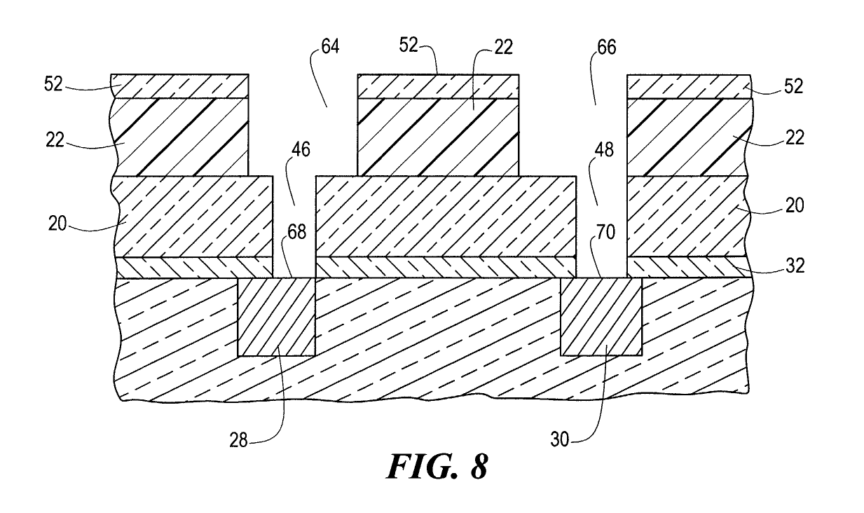

Referring also to FIG. 8, subsequent to the etch of material 22, nitride etch stop layer 32 is removed in a dry etch in a fluorine-containing plasma chemistry. A portion of the thicker nitride hard mask layer 52 remains over low-k material 22. Portions 68, 70 of metal 27 comprising electrical conductors 28, 30 are thereby exposed at the bottom of vias 46, 48. Second layer of metal 18 is then deposited into trenches 64, 66 and vias 46, 48. Second layer of metal 18 makes contact to the first layer of metal 16, disposed in trenches 25, 26, as shown in FIGS. 1 and 2. Second layer metal 18 is a composite metal structure. First, a liner material is deposited. The liner material is TiN, deposited by chemical vapor deposition (CVD) in an Endura 5500 system from AMAT. Alternatively, liner material is TaN. Then, metal fill layer is formed by first depositing a copper seed by physical vapor deposition (PVD) in an Endura 5500 system from Applied Materials, Inc. and then depositing copper by electroplating in a SABRETM system from Novellus Systems, Inc. Finally, surface 72 is planarized by removing liner material and metal fill from over remaining portion of layer 52 by chemical-mechanical polishing (CMP).

A number of embodiments of the invention have been described. Nevertheless, it will be understood that various modifications may be made without departing from the spirit and scope of the invention. For example, various types of low-k organic materials can be used as the second layer of the interlevel dielectric. The organic material can be either spun on or deposited by chemical vapor deposition. Further, the second layer of the interlevel dielectric can be a low-k inorganic material. Moreover, liner material may be a sandwich structure including TaN deposited by PVD, TiN deposited by CVD, and tantulum deposited by PVD. A metal fill layer can be a copper seed layer deposited by PVD, and copper deposited by electroplating. Accordingly, other embodiments are within the scope of the following claims.

What is claimed is:

1. A method for forming a semiconductor device, such method comprising:
forming a first dielectric layer over a substrate, the first dielectric having a first dielectric constant characteristic;
forming a via in a portion of the first dielectric layer;
forming a second dielectric layer over the first dielectric layer, the second dielectric layer having a second dielectric constant characteristic lower than the first dielectric constant; and
forming a trench in a portion of the second dielectric layer with a portion of the trench being formed over the via.

2. The method of claim 1, wherein the first dielectric layer is an inorganic material.

3. The method of claim 2, wherein the first dielectric layer is an oxide.

4. The method of claim 3, wherein the first dielectric layer is formed by chemical vapor deposition.

5. The method of claim 1, wherein the second dielectric layer is an organic material.

6. The method of claim 5, wherein the second dielectric layer is formed by spinning the organic material over the substrate.

7. The method of claim 1, further comprising depositing a metal layer into the via and the trench.

8. A method for forming a semiconductor device, such method comprising:
depositing a first metallization layer over a substrate;
patterning the first metallization layer;
forming a first dielectric layer over the first metallization layer;
forming a via in a portion of the first dielectric layer;
forming a second dielectric layer over the first dielectric layer, such second dielectric layer being formed with a dielectric constant lower than the dielectric constant of the first dielectric layer;
forming a trench in a portion of the second dielectric layer with a portion of said trench being formed over the via; and
depositing a second metallization layer, the second metallization layer fills the via and the trench, and a portion of the first metallization layer is in contact with a portion of the second metallization layer.

9. The method of claim 8, wherein the via has a first width and the trench has a second width and the second width is at least equal to the first width.

10. A method for forming a semiconductor device, such method comprising:
forming an inorganic dielectric layer over a substrate;
forming a via in a portion of the inorganic dielectric layer;
forming an organic dielectric layer over the inorganic dielectric layer; and
forming a trench in a portion of the organic dielectric layer with a portion of said trench being formed over the via.

11. A semiconductor structure, comprising:
a semiconductor substrate;
a dielectric layer disposed over the substrate, said dielectric layer having a first trench;
a first metal layer disposed in the first trench;
a first layer of a material having a first dielectric constant disposed over the dielectric layer, said first layer having a via in registration with the first metal layer disposed in the first trench;
a second layer of a material having a second dielectric constant disposed over the first layer of material, said second layer having a second trench in registration with the via and the first dielectric constant is higher than the second dielectric constant; and
a second metal layer disposed in the via and second trench, said second metal layer being in contact with said first metal layer.

12. The structure of claim 11, wherein the first layer of a material comprises an inorganic material.

13. The structure of claim 11, wherein the second layer of a material comprises an organic material.

14. A semiconductor structure, comprising:
a semiconductor substrate;
a dielectric layer disposed over the substrate, said dielectric layer having a first trench;
a first metal layer disposed in the first trench;
a layer of an inorganic dielectric material disposed over the dielectric layer, said inorganic dielectric layer having a via in registration with the metal disposed in the first trench;
a layer of an organic material disposed over the layer of inorganic dielectric material, said layer of organic material having a second trench in registration with the via; and
a second metal layer disposed in the via and second trench, said second metal layer being in contact with said first metal layer.
